(19) United States
(12) Patent Application Publication
(10) Pub. No.: US 2025/0003061 A1
(43) Pub. Date: Jan. 2, 2025

(54) INTERFACE TUNING FOR EROSION AND CORROSION RESISTANT COATINGS FOR SEMICONDUCTOR COMPONENTS

(71) Applicant: Applied Materials, Inc., Santa Clara, CA (US)

(72) Inventors: Nitin Deepak, Thane (IN); Ryan Sheil, Santa Cruz, CA (US); Katherine Woo, Santa Clara, CA (US); Juan Carlos Rocha-Alvarez, San Carlos, CA (US); Jennifer Y. Sun, Fremont, CA (US)

(73) Assignee: Applied Materials, Inc., Santa Clara, CA (US)

(21) Appl. No.: 18/343,351

(22) Filed: Jun. 28, 2023

(51) Int. Cl. C23C 16/40; C23C 16/34

(52) U.S. Cl. CPC C23C 16/403; C23C 16/34; C23C 16/405

(57) ABSTRACT

Exemplary processing methods may include providing a component for semiconductor processing to a processing region of a processing chamber. The methods may include providing one or more interface deposition precursors to the processing region. The methods may include depositing a layer of interface material on the component for semiconductor processing in the processing region. The methods may include providing one or more coating deposition precursors to the processing region. The methods may include depositing a layer of coating material on the component for semiconductor processing in the processing region.

### TECHNICAL FIELD

The present technology relates to coating processes and semiconductor chamber components. More specifically, the present technology relates to modified components and component materials.

### BACKGROUND

Integrated circuits are made possible by processes which produce intricately patterned material layers on substrate surfaces. Producing patterned material on a substrate requires controlled methods of formation and removal of exposed material. Deposition and removal operations may include producing a remote plasma or a local plasma in a processing region of a semiconductor processing chamber, for example, between a showerhead or gas distributor and a substrate support. Components of the semiconductor processing chamber may be exposed to plasma species during processing. Where the components exposed to corrosive species on a repeated basis, degradation of the components and contamination of substrates being processed may occur. Accordingly, a top coating may be provided to protect the underlying component from corrosion and/or erosion. However, differences in top coating materials and underlying component materials may frustrate the performance of the top coating.

Thus, there is a need for improved systems and system components that can be used to produce high quality devices and structures. These and other needs are addressed by the present technology.

### SUMMARY

Exemplary processing methods may include providing a component for semiconductor processing to a processing region of a processing chamber. The methods may include providing one or more interface deposition precursors to the processing region. The methods may include depositing a layer of interface material on the component for semiconductor processing in the processing region. The layer of interface material may be an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material. The methods may include providing one or more coating deposition precursors to the processing region. The methods may include depositing a layer of coating material on the component for semiconductor processing in the processing region.

In some embodiments, the component for semiconductor processing may include a metal-containing material or a metallic-containing material. The component for semiconductor processing may include a ceramic-containing material. The ceramic-containing material may include one or more metals and one or more of oxygen, fluorine, and nitrogen. The ceramic-containing material may be or include aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}). The layer of interface material may be characterized by a coefficient of thermal expansion (CTE) greater than the component for semiconductor processing and less than the layer of coating material. The metal-containing precursor may include aluminum, calcium, erbium, lanthanum, magnesium, scandium, titanium, yttrium, or zirconium. The one or more coating deposition precursors comprise a fluorine-containing precursor. The fluorine-containing precursor may be or include hydrogen fluoride (HF), ammonium fluoride (NH₄F), ammonium bifluoride ([NH₄]F·HF), a HF-pyridine complex, nitrogen trifluoride (NF₃), hexafluoroisopropanol (HFIP), tetrafluoropropanol (TFP), hexafluoro-acetylacetonate (HHFAC), titanium tetrafluoride (TiF₄), tantalum pentafluoride (TaF₅), or tungsten hexafluoride (WF₆), or a fluorine-containing plasma. The layer of coating material may be or include aluminum fluoride (AlF₃), aluminum oxyfluoride (AlOₓF_{y}), calcium fluoride (CaF₂), calcium oxyfluoride (CaOₓF_{y}), magnesium fluoride (MgF₂), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}), or a combination thereof. The one or more coating deposition precursors may further include an oxygen-containing precursor. The oxygen-containing precursor may be or include steam (H₂O), molecular oxygen (O₂), ozone (O₃), nitrous oxide (N₂O), hydrogen peroxide (H₂O₂), an oxygen-containing plasma, an alcohol-based compound, or an alcohol-based plasma. The one or more coating deposition precursors may further include a nitrogen-containing precursor. The methods may include generating plasma effluents of the one or more coating deposition precursors. A temperature within the processing region may be maintained at less than or about 2,000° C. The component for semiconductor processing may be or include a lid, a nozzle, a face plate, a gas distribution plate, a heater, a screw, a substrate support, a support platen, a liner, an edge ring, a process kit ring, or a lift pin.

Some embodiments of the present technology may encompass processing methods. The methods may include providing a component for semiconductor processing to a processing region of a processing chamber. The methods may include depositing a layer of interface material on the component for semiconductor processing in the processing region. The layer of interface material may be or include an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, a metal-oxygen-fluorine-and-nitrogen-containing material, a material comprising one or more metals and one or more of oxygen, fluorine, and nitrogen, or combinations thereof. The methods may include depositing a layer of coating material on the layer of interface material in the processing region. Depositing the layer of coating material may include exposing the component for semiconductor processing to a first coating precursor, purging the processing region, and exposing the component for semiconductor processing to a second coating precursor. The layer of coating material may include reaction products of the first coating precursor and the second coating precursor. A temperature within the processing chamber may be maintained at greater than or about 400° C.

In some embodiments, the component for semiconductor processing may be or include aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}). The layer of coating material may be or include a metal-fluorine-and-oxygen-containing material. The methods may include generating plasma effluents of the first coating precursor, the second coating precursor, or both.

Some embodiments of the present technology may encompass components for semiconductor processing. The components may include a ceramic, metallic, or non-metallic component for semiconductor processing. The components may include a layer of interface material on the component for semiconductor processing. The layer of interface material may be or include an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, a metal-oxygen-fluorine-and-nitrogen-containing material, a material comprising one or more metals and one or more of oxygen, fluorine, and nitrogen, or combinations thereof. The components may include a layer of coating material on the layer of interface material.

In some embodiments, the component for semiconductor processing may be or include a lid, a nozzle, a face plate, a gas distribution plate, a heater, a screw, a substrate support, a support platen, a liner, an edge ring, a process kit ring, or a lift pin.

Such technology may provide numerous benefits over conventional techniques. For example, the methods may provide a coated component for semiconductor processing exhibiting improved compatibility with plasma processing applications. For example, a component may be chemically reduced to remove a passivation layer on the grains of the component. In this way, an interface layer may be formed on the component and a layer of coating material may be a coated onto the interface layer, for example, by atomic layer deposition. The interface coating may provide coefficient of thermal expansion (CTE) modulation between the component and the coating material, increase adhesion, serve as a diffusion barrier, control nucleation, control or remove contamination, or control porosity. As such, the coated component for semiconductor processing may exhibit improved thermal, mechanical, and/or chemical properties, including in halogen plasma environments at which semiconductor processing operations are undertaken. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic view of an exemplary processing chamber according to some embodiments of the present technology.

FIG. 2 shows exemplary operations in a deposition method according to some embodiments of the present technology.

FIG. 3 show schematic views of a component during operations in a deposition method according to some embodiments of the present technology.

FIG. 4 show schematic views of an exemplary processing chamber component formed the method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As part of semiconductor processing technology, deposition and removal operations may include producing a remote plasma or a local plasma in a processing region of a semiconductor processing chamber, for example, between a showerhead or gas distributor and a substrate support. Components of the semiconductor processing chamber may be or include a metal material, a metallic material, and/or a ceramic material. In order to protect the metal material, the metallic material, and/or the ceramic material during operations using plasma, a coating material may be provided to protecting the underlying material. The coating material may be a combination of materials, such as oxides, nitrides, fluorides, metal oxides, metal nitrides, and/or metal fluorides, as well as mixed metal materials. However, these coating materials are conventionally formed directly on the component, and may be limited or less effective than desired.

Conventional technologies that have formed coating materials directly on components to be protected may suffer from adhesion issues and CTE differences that result in cracking and/or flaking of the coating material. The present technology may overcome these limitations by forming an interface material on the component prior to forming the coating material. The interface materials may have better adhesion to both the components and the coating materials. Additionally, the interface layer may have a CTE between the CTE of the component and the CTE of the coating material, which may mitigate differences in the CTE of the component and the CTE of the coating material. Further, the interface materials may control diffusion, nucleation, contamination, and/or porosity. The interface materials may be formed using specific elements to form a stable phase, such as a spinel or a garnet phase, which may increase effectiveness of the coating materials. By depositing the coating material on the interface material, the lifetime and effectiveness of the coating material may be increased. This may enable preparation of coated components for semiconductor processing for application in, for example, plasma processing chamber components with tailored thermal, mechanical, and chemical properties at conditions used for semiconductor processing. As a result, the coated components for semiconductor processing may be implemented in semiconductor processing chambers that are exposed to plasma operations.

After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

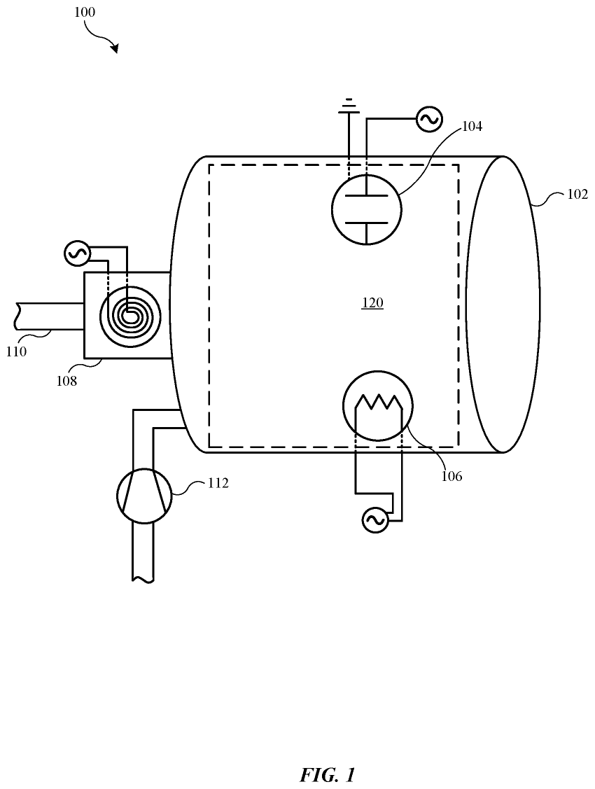

FIG. 1 shows a schematic view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form coated components for semiconductor processing according to some embodiments of the present technology, although it is to be understood that the methods may similarly be performed in any chamber within which film formation may occur. The processing chamber 100 may include a chamber body 102, a plasma system 104 inside the chamber body 102, a temperature control system 106, and a remote plasma system 108 coupled with the chamber body 102 and configured to provide plasma effluents to a processing region 120 of the chamber body 102.

A component for semiconductor processing may be provided to the processing region 120 through a material feedthrough, such as a port or conduit, which may be sealed for processing using a slit valve, gate valve, or door. Precursors, as described below, may be provided to the chamber 100 through a gas supply system 110. While FIG. 1 illustrates a single inlet for the gas supply system 110, the chamber 100 may include multiple gas inlets coupled with the chamber body 102 at one or more locations. For example, a plasma precursor may be introduced to the chamber body through the remote plasma system 108, while a second gas inlet may provide gases for which plasma dissociation would negatively impact the deposition process. Gases may be removed from the chamber body 102 by a gas removal system 112. The gas removal system 112 may include a vacuum system, configured to facilitate reduced pressure operation during deposition processes and to evacuate the chamber to remove process effluents and unreacted process gases. Measurement and control systems may be coupled with the chamber to measure operating pressure in one or more places, such as in the gas supply system 110, the gas removal system 112, or in the processing region 120. In another example, the temperature control system 106 may include temperature sensors and a heating element configured to provide heat to the processing region 120 or to remove heat from the processing region 120. In this way, the chamber 100 may implement controlled deposition and removal processes, such as plasma etching and removal, and atomic layer deposition.

As part of implementing plasma processing of components for semiconductor processing in the chamber 100, in accordance with the methods described below, the plasma system 104 may be configured to form a plasma within the processing region 120. The plasma system 104 may be or include an indirect plasma system, such as an RF capacitively-coupled plasma, configured to form a plasma within the processing region 120 by generating sufficiently strong electric fields internal to the chamber body 102. In some embodiments, the plasma system 104 may be or include a direct plasma system, such that one or more electrode surfaces are disposed within the chamber body. In this way, the processing region 120 may be defined between a live electrode and a reference ground electrode of the plasma system 104. The plasma system 104 may also include control systems and power supply systems, such as impedance matching circuits and 13.56 MHz RF power supplies.

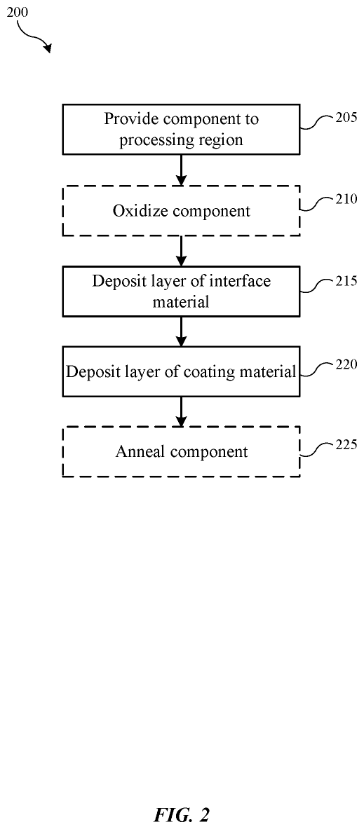

Similarly, the remote plasma system 108 may be or include a direct plasma system or an indirect plasma system, such as an inductively coupled RF plasma system or a capacitively coupled RF plasma system, which may be configured to decompose a precursor into plasma effluents that can be provided to the processing region 120. For example, the gas supply system 110 may include a quartz inlet tube coupled with a feedthrough to the chamber body 102. In such an arrangement, the remote plasma system 108 may be or include an ICP or a CCP system disposed external to the quartz inlet tube and configured to form a plasma within the quartz inlet tube. As further described in reference to FIG. 2, the precursor may include an inert carrier gas and a reaction precursor that may be or include a vapor or a gas. In this way, the remote plasma system 108 may form an indirect plasma in the precursor and may decompose the precursor. The decomposed precursor may be or include plasma effluents, which may be or include carrier gas, unreacted precursor, and plasma generated species. The plasma generated species may serve as reactants in a chemical reaction mediated deposition process, such as conformal deposition processes including, but not limited to, chemical vapor deposition (CVD) and atomic layer deposition (ALD), and direct line of sight deposition processes including, but not limited to, physical vapor deposition (PVD), ion beam (IB) deposition, electron beam (EB) deposition, or electron beam ion-assisted deposition (EB-IAD). As with the plasma system 104, remote plasma system 108 may also include control systems and power supply systems, such as impedance matching circuits and 13.56 MHz RF power supplies.

The temperature control system 106 may be configured to maintain an internal temperature in the processing region in accordance with a processing method. For example, as part of atomic layer deposition, a deposition substrate, such as a component for semiconductor processing, may be heated to a reaction temperature at which a particular reaction product is favored. In an illustrative example, a surface reaction that forms a layer of material on the deposition substrate may be thermodynamically favored at an elevated temperature. As such, the temperature control system 106 may provide heat to the processing region. In some embodiments, the temperature control system may be at least partially integrated into the plasma system 104. For example, an electrode of the plasma system 104 may incorporate heating and/or cooling elements, permitting the plasma system to operate within a range of operating temperatures.

In some embodiments, the chamber 100 may be configured to prepare coated components for semiconductor processing for which the components are coated with one or more layers of material. As described in reference to methods and systems, below, the chamber 100 may permit the preparation of improved coated components for semiconductor processing, which may be incorporated into semiconductor processing systems. Such components may exhibit improved thermal, mechanical, and/or chemical properties at processing conditions that are characteristic of plasma deposition and removal operations as part of semiconductor processing.

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

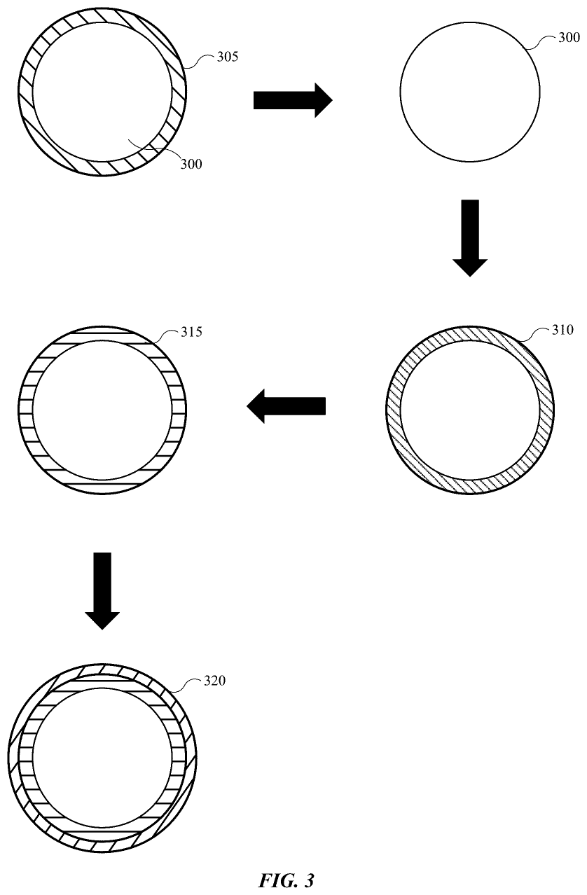

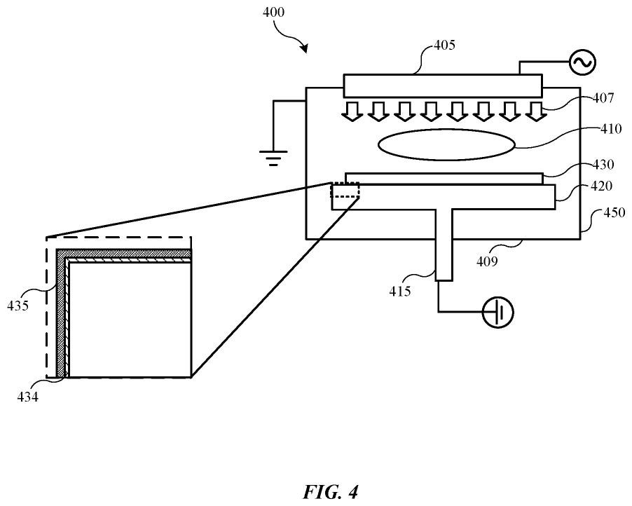

Method 200 describes operations shown schematically in FIG. 3, the illustrations of which will be described in conjunction with the operations of method 200. FIG. 4 illustrates an exemplary semiconductor processing system incorporating materials produced according to some embodiments of the method 200. It is to be understood that FIGS. 3-4 illustrate only partial schematic views, and a processing system may include subsystems as illustrated in the figures, as well as alternative subsystems, of any size or configuration that may still benefit from aspects of the present technology.

FIG. 3 show schematic views of a component for semiconductor processing 300 during operations of the method 200 according to some embodiments of the present technology. In some embodiments, the method 200 may include one or more operations preceding those illustrated in FIG. 2. For example, one or more processes may be implemented to form the component for semiconductor processing 300 from a feedstock material. For example, the component for semiconductor processing 300 may be formed by chemically converting an oxide to a nitride, and may be cleaned, for example, by baking, etching, or degreasing. Examples of nitride synthesis may include, but are not limited to, carbo-thermal nitridization and/or direct nitridization. Furthermore, the component for semiconductor processing 300 may be introduced into a processing chamber, such as the chamber 100, bearing a passivation layer 305. For example, the component for semiconductor processing 300 may be or include aluminum nitride, which, through exposure to oxygen during cleaning or through exposure to air at ambient conditions, may develop an oxide passivation layer.

Method 200 may include additional operations prior to initiation of the listed operations. For example, as illustrated in FIG. 3, method 200 may include removing a passivation layer 305, such as a native oxide or surface oxide, prior to coating the component. Removing the passivation layer may include providing hydrogen to the processing region of the chamber. Hydrogen may permit a hydrogen plasma, a hydrogen-rich plasma, or a trace-hydrogen plasma to be formed in the processing region, as an approach to chemically reducing the passivation layer 305. The hydrogen may be provided to the processing region of the chamber with an inert carrier gas. In plasma systems, inert carrier gases, also referred to as “forming gases”, facilitate plasma ignition and control of plasma conditions. For example, providing the hydrogen with a given inert gas fraction may permit the plasma to operate under controlled plasma conditions, such as ionization fraction, ion temperature, or electron temperature. Subsequent introducing hydrogen into the processing region, the method 200 may include striking a plasma in the processing region. The plasma may be or include a hydrogen plasma, and as such it may include energetic plasma species, such as hydrogen ions, hydrogen radicals, or metastable diatomic hydrogen. The hydrogen plasma may be formed in the processing region while the component for semiconductor processing 300 is positioned in the processing region. The plasma treatment may be performed based on hydrogen supplied with a carrier gas, such as argon or helium, for generating the plasma, and the hydrogen may constitute a percentage material in the gas mixture.

During method 200, the component for semiconductor processing 300 may be positioned in the processing region. At operation 205, method 200 may include delivering the component for semiconductor processing 300 to the processing region of the processing chamber, such as processing chamber 100 described above, or other chambers that may include components as described above. The component for semiconductor processing 300 may include a plurality of individual particles. The particles making up the component for semiconductor processing 300 may be any type of material and may be a metal-containing material, a metallic-containing material, or a ceramic-containing material in embodiments. For example, the particles of component for semiconductor processing 300 may include one or more metals and one or more of oxygen, fluorine, and nitrogen (e.g., a material comprising one or more metals and one or more of oxygen, fluorine, and nitrogen), and may be or include, but are not limited to, aluminum, yttrium, magnesium, titanium, stainless steel, Hastelloy, aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}), or any combination thereof.

In some embodiments, method 200 may optionally include oxidizing the component for semiconductor processing 300 at optional operation 210. Optional operation 210 may include introducing oxygen into the processing region of the chamber. Introducing oxygen into the processing region as part of plasma enhanced deposition may permit the formation of a controlled oxide layer on the component for semiconductor processing 300. In contrast to the passivation layer 305, the controlled oxide layer may be formed under controlled conditions, such as in an oxygen plasma in the processing region, such that an oxide layer may be formed on the component for semiconductor processing 300 with a characteristic and uniform thickness. Additionally or alternatively, optional operation 210 may include thermal oxidation of the component for semiconductor processing 300 subsequent removal of the passivation film 305. A surface oxide layer may impart improved control of thermal, mechanical, and/or chemical properties in a component for semiconductor processing 300, for example, by acting as a diffusion barrier. In this way, it may be advantageous to reduce the component for semiconductor processing 300 to remove the passivation layer 305, and subsequently to oxidize the component for semiconductor processing 300 under controlled conditions to reform an oxide layer.

Subsequent oxidizing the component for semiconductor processing 300 at optional operation 210, method 200 may include forming a layer of interface material 310 on the component for semiconductor processing 300 at operation 310. Forming the layer of interface material 310 on the component for semiconductor processing 300 may include undertaking operations of an ALD process, whereby the component for semiconductor processing 300 may be uniformly coated. However, as previously discussed, forming the layer of interface material 310 may be performed using a variety of deposition methods. For example, operation 215 may include providing one or more interface deposition precursors or introducing plasma effluents of the one or more interface deposition precursors to the processing region. Plasma effluents may be or include plasma generated species that are formed by a remote plasma system, such as remote plasma system 108 of FIG. 1, in communication with the processing region. However, it is also contemplated that the plasma effluents may be formed locally to the component for semiconductor processing 300. Introducing the plasma effluents may include introducing a carrier gas including the plasma effluents. In this way, introducing the plasma effluents into the processing region may expose the component for semiconductor processing 300 to plasma effluents of one or more interface deposition precursors that have been subjected to plasma decomposition. Plasma effluents, therefore, may be or include ions, activated radicals, metastable species, and other decomposition products, and may be characterized by average energy distribution lower than that of a direct plasma system. Exposing the component for semiconductor processing 300 to the plasma effluents may, in turn, result in the formation of an adsorbed monolayer of plasma effluents on the surface of the component for semiconductor processing 300 that serves as a precursor to the formation of the layer of interface material 310. It is also contemplated that the component for semiconductor processing 300 may be exposed to thermal and/or chemical effluents of the first precursor in addition to or alternative to plasma effluents.

In a second operation of atomic layer deposition, the plasma effluents, if formed, of the first precursor may be removed from the processing region by purging the processing region of gas, while retaining the component for semiconductor processing 300 bearing the adsorbed monolayer. Purging the processing region may be implemented using a gas removal system, such as the gas removal system 112 of FIG. 1. Subsequent purging, a second precursor may be decomposed into second plasma effluents, such that the component for semiconductor processing 300 is exposed to the second plasma effluents, if formed. However, it is also contemplated that the component for semiconductor processing 300 may be exposed to thermal and/or chemical effluents of the second precursor in addition to or alternative to plasma effluents. The second precursor may be chosen such that it decomposes into plasma generates species that react with the monolayer adsorbed on the component for semiconductor processing 300 to form the layer of interface material 310. Subsequent forming the layer of interface material 310, the unreacted plasma effluents and reaction byproducts may be removed by the gas removal system.

In some embodiments, the first and second precursors may be selected such that the layer of interface material 310 may be provide one or more benefits to a subsequently formed topcoat, as further discussed below. For example, the layer of interface material 310 may provide CTE modulation between the component and the topcoat, increase adhesion, serve as a diffusion barrier, control nucleation, control or remove contamination, or control porosity. In embodiments, the layer of interface material 310 may be an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material.

In embodiments, the one or more interface deposition precursors used may be dependent on the layer of interface material 310 to be formed. For example, one or more interface deposition precursors may include an oxygen-containing precursor, a nitrogen-containing precursor, a fluorine-containing precursors, a silicon-containing precursor, or a metal-containing precursor may be used. The oxygen-containing precursor may be any oxygen-containing material used or useful in semiconductor processing. For example, the oxygen-containing precursor may be or include steam (H₂O), molecular oxygen (O₂), ozone (O₃), nitrous oxide (N₂O), hydrogen peroxide (H₂O₂), an oxygen-containing plasma, an alcohol-based compound, or an alcohol-based plasma. The nitrogen-containing precursor may be any nitrogen-containing material used or useful in semiconductor processing. For example, the nitrogen-containing precursor may be or include nitrous oxide (N₂O), molecular nitrogen (N₂), ammonia (NH₃), hydrazine (N₂H₄), or nitrogen-based plasma. The fluorine-containing precursor may be any fluorine-containing material used or useful in semiconductor processing. For example, the fluorine-containing precursor may be or include hydrogen fluoride (HF), ammonium fluoride (NH₄F), ammonium bifluoride ([NH₄]F·HF), a HF-pyridine complex, nitrogen trifluoride (NF₃), hexafluoroisopropanol (HFIP), tetrafluoropropanol (TFP), hexafluoro-acetylacetonate (HHFAC), titanium tetrafluoride (TiF₄), tantalum pentafluoride (TaF₅), or tungsten hexafluoride (WF₆), or a fluorine-containing plasma. The silicon-containing precursor may be any silicon-containing material used or useful in semiconductor processing. For example, the silicon-containing precursor may be or include silane (SiH₄), disilane (Si₂H₆), silicon tetrafluoride (SiF₄), silicon tetrachloride (SiCl₄), dichlorosilane (SiH₂Cl₂), or tetraethyl orthosilicate (TEOS). The metal in the metal-containing precursor may be or include, for example, a rare earth element or a transition metal. For example, the metal-containing precursor may include aluminum, calcium, erbium, lanthanum, magnesium, scandium, titanium, yttrium, or zirconium. In embodiments, the metal-containing precursor may include a hexafluoroacetylacetone compound. For example, the metal may be in solution with hexafluoroacetylacetone (hfac). For example, the metal-containing precursor may be or include, but is not limited to, Mg(hfac)₂, or Mg(hfac)(dmg)H₂O, Al(hfac)₃, Y(hfac)₃.

In embodiments, the layer of interface material 310 may be a multilayer stack, a nano-laminate stack, or a micro-laminate stack of the one or more materials discussed above. Additionally, the layer of interface material 310 may be formed in a phase with increased stability. The increased stability may contribute to CTE modulation between the component and the coating material, increased adhesion, increased control of diffusion, nucleation, contamination, and/or porosity. In embodiments, the layer of interface material 310 may be in various crystallized phases, including spinel, garnet, and any other phase.

Depending on the precursors utilized during the deposition, the layer of interface material 310 may include, for example, an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material, as previously discussed. In embodiments, the layer of interface material 310 may include multiple metals. For example, the layer of interface material 310 may be a magnesium-containing material, such as an aluminum-magnesium-and-oxygen-containing material (AlₓMg_{y}O), an yttrium-and-aluminum-containing material, such as yttrium aluminum garnet (YAG), or an erbium-and-aluminum-containing material, such as erbium aluminum garnet (EAG).

Subsequent depositing the layer of interface material 310 at operation 215, method 200 may include forming a layer of coating material 315 on the component for semiconductor processing 300 at operation 220. Similar to forming the layer of interface material 310, forming the layer of coating material 315 on the component for semiconductor processing 300 may include undertaking operations of an ALD process, whereby the component for semiconductor processing 300 may be uniformly coated. However, as previously discussed, forming the layer of coating material 315 may be performed using a variety of deposition methods. For example, operation 220 may include providing one or more coating deposition precursors or introducing plasma effluents of the one or more coating deposition precursors to the processing region. Plasma effluents may be or include plasma generated species that are formed by a remote plasma system, such as remote plasma system 108 of FIG. 1, in communication with the processing region. However, it is also contemplated that the plasma effluents may be formed locally to the component for semiconductor processing 300. Introducing the plasma effluents may include introducing a carrier gas including the plasma effluents. In this way, introducing the plasma effluents into the processing region may expose the component for semiconductor processing 300 to plasma effluents of one or more precursors that have been subjected to plasma decomposition. Plasma effluents, therefore, may be or include ions, activated radicals, metastable species, and other decomposition products, and may be characterized by average energy distribution lower than that of a direct plasma system. Exposing the component for semiconductor processing 300 to the plasma effluents may, in turn, result in the formation of an adsorbed monolayer of plasma effluents on the surface of the component for semiconductor processing 300 that serves as a precursor to the formation of the layer of coating material 315.

In a second operation of atomic layer deposition, the plasma effluents of the first precursor may be removed from the processing region by purging the processing region of gas, while retaining the component for semiconductor processing 300 bearing the adsorbed monolayer. Purging the processing region may be implemented using a gas removal system, such as the gas removal system 112 of FIG. 1. Subsequent purging, a second precursor may be decomposed into second plasma effluents, such that the component for semiconductor processing 300 is exposed to the second plasma effluents. The second precursor may be chosen such that it decomposes into plasma generates species that react with the monolayer adsorbed on the component for semiconductor processing 300 to form the layer of coating material 315. Subsequent forming the layer of coating material 315, the unreacted plasma effluents and reaction byproducts may be removed by the gas removal system.

In some embodiments, the first and second precursors may be selected such that the layer of coating material 315 may be or include a corrosion-resistant and/or erosion-resistant additive to improve the mechanical properties of the component for semiconductor processing 300. For example, the layer of coating material 315 may be an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material. The oxygen-containing material may be or include, for example, a silicon-and-oxygen-containing material. The nitrogen-containing material may be or include, for example, a silicon-and-nitrogen-containing material. The fluorine-containing material may be or include, for example, a fluorine-doped silicon-containing material.

In embodiments, the one or more coating deposition precursors used may be dependent on the layer of coating material 315 to be formed. For example, one or more of an oxygen-containing precursor, a nitrogen-containing precursor, a fluorine-containing precursors, a silicon-containing precursor, or a metal-containing precursor may be used. The oxygen-containing precursor may be any oxygen-containing material used or useful in semiconductor processing. For example, the oxygen-containing precursor may be or include steam (H₂O), molecular oxygen (O₂), ozone (O₃), nitrous oxide (N₂O), hydrogen peroxide (H₂O₂), an oxygen-containing plasma, an alcohol-based plasma, or an alcohol-based plasma. The nitrogen-containing precursor may be any nitrogen-containing material used or useful in semiconductor processing. For example, the nitrogen-containing precursor may be or include nitrous oxide (N₂O), molecular nitrogen (N₂), ammonia (NH₃), hydrazine (N₂H₄), or nitrogen-based plasma. The fluorine-containing precursor may be any fluorine-containing material used or useful in semiconductor processing. For example, the fluorine-containing precursor may be or include hydrogen fluoride (HF), ammonium fluoride (NH₄F), ammonium bifluoride ([NH₄]F· HF), a HF-pyridine complex, nitrogen trifluoride (NF₃), hexafluoroisopropanol (HFIP), tetrafluoropropanol (TFP), hexafluoro-acetylacetonate (HHFAC), titanium tetrafluoride (TiF₄), tantalum pentafluoride (TaF₅), or tungsten hexafluoride (WF₆), or a fluorine-containing plasma. The silicon-containing precursor may be any silicon-containing material used or useful in semiconductor processing. For example, the silicon-containing precursor may be or include silane (SiH₄), disilane (Si₂H₆), silicon tetrafluoride (SiF₄), silicon tetrachloride (SiCl₄), dichlorosilane (SiH₂Cl₂), or tetraethyl orthosilicate (TEOS). The metal in the metal-containing precursor may be or include, for example, a rare earth element or a transition metal. For example, the metal-containing precursor may include aluminum, calcium, erbium, lanthanum, magnesium, scandium, titanium, yttrium, or zirconium. In embodiments, the metal-containing precursor may include a hexafluoroacetylacetone compound. For example, the metal may be in solution with hexafluoroacetylacetone (hfac). For example, the metal-containing precursor may be or include, but is not limited to, Mg(hfac)₂, or Mg(hfac)(dmg)H₂O, Al(hfac)₃, Y(hfac)₃.

Depending on the precursors utilized during the deposition, the layer of coating material 315 may include, for example, aluminum fluoride (AlF₃), aluminum oxyfluoride (AlOₓF_{y}), calcium fluoride (CaF₂), calcium oxyfluoride (CaOₓF_{y}), magnesium fluoride (MgF₂), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), scandium oxyfluoride (ScOₓF_{y}), or combinations thereof, although any other layer of material previously discussed is contemplated, including a layer of coating material 315 including multiple metals. In one exemplary embodiment, the layer of coating material 315 may be a fluorine-containing material.

In embodiments, additional layers of material may be formed on the component for semiconductor processing 300, or the layer of coating material 315 may include additional elements. The additional layers of material or the layer of coating material 315 may include multiple different materials, including oxide, nitride, or fluoride materials, in addition to the metal-containing material. Based on the precursors used, the additional layers of material may be an oxide, a nitride, or an oxynitride. For example, additional layers of material may be or include, but are not limited to, aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), or zirconium nitride (ZrN).

In some embodiments, the constituent operations of the operation 220 may be repeated to deposit multiple monolayers, such that the layer of coating material 315 may be formed on a monolayer-by-monolayer basis, and the thickness of the layer of coating material 315 may be an integer multiple of the monolayer thickness and the number of repetitions of the operation 220. Furthermore, following operation 220, a second layer of coating material 320 may be formed overlying the layer of coating material 315, by repeating the operation with either the same set of first and second precursors or a different set of first and second precursors. For example, where the layer of coating material 315 may be or include aluminum fluoride, the second material 320 may be or include a different fluoride, such as yttrium aluminum fluoride, or another oxide, nitride, or fluoride. As such, a coated component for semiconductor processing 300 by the method 200 may include a controlled oxide layer, the layer of interface material 310, the layer of coating material 315, and one or more additional layers of different materials, such as the second layer of coating material 320.

A flowrate of the coating precursors or deposition precursors introduced to the chamber may depend at least in part on one or more parameters of the chamber, the component for semiconductor processing 300, or the method 200. For example, the flowrate may be adjusted such that a plasma may form with a sufficient energy density or species density, such as ions, free electrons, or activated precursor, to facilitate, for example, reduction of the passivation layer 305 or deposition of the layer of coating material 315.

Related to the flowrate of the coating precursors or deposition precursors, a pulse size of the first precursor or of the second precursor may be less than or about 75 minutes. At times greater than 75 minutes, the component for semiconductor processing 300 may be fully saturated and no longer accept the precursor to form a monolayer of material. Accordingly, the pulse size of the first precursor or of the second precursor may be less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, less than or about 50 seconds, less than or about 40 seconds, less than or about 30 seconds, less than or about 20 seconds, less than or about 10 seconds, or less.

Similarly a pulse size of the purge gas to purge the first precursor may be less than or about 120 minutes, such as less than or about 110 minutes, less than or about 100 minutes, less than or about 90 minutes, less than or about 80 minutes, less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less. The purge may be a longer duration than the precursor in order to ensure the precursors are fully removed from the processing region.

During method 200, such as during operations 210 and/or 215, a temperature within the processing chamber may be maintained at less than or about 2,000° C. While higher temperatures may be employed, depositions of the present technology may be operated at temperatures less than or about 1,750° C., such as less than or about 1,500° C., less than or about 1,250° C., less than or about 1,000° C., less than or about 900° C., less than or about 800° C., less than or about 750° C., less than or about 725° C., less than or about 700° C., less than or about 675° C., less than or about 650° C., less than or about 625° C., less than or about 600° C., less than or about 575° C., less than or about 550° C., less than or about 525° C., less than or about 500° C., less than or about 480° C., less than or about 460° C., less than or about 440° C., less than or about 420° C., less than or about 400° C., less than or about 380° C., less than or about 360° C., less than or about 340° C., less than or about 320° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., less than or about 80° C., less than or about 60° C., less than or about 40° C., less than or about 20° C., or less. However, higher temperatures may increase the deposition of the material which may increase throughput. In embodiments, an ALD deposition performed at higher temperatures may make the deposition proceed more as a CVD deposition. Accordingly, the temperature within the processing chamber may be maintained at greater than or about 300° C., such as greater than or about 350° C., greater than or about 400° C., greater than or about 450° C., greater than or about 500° C., or more.

Additionally, during method 200, such as during operations 210 and/or 215, a pressure within the processing chamber may be maintained at less than or about 50 mTorr. Again, while higher pressures may be employed, depositions of the present technology may be operated at pressures less than or about 50 m Torr, such as less than or about 45 m Torr, less than or about 40 m Torr, less than or about 35 mTorr, less than or about 30 m Torr, less than or about 25 m Torr, less than or about 20 m Torr, less than or about 15 mTorr, less than or about 10 m Torr, less than or about 7 m Torr, less than or about 5 mTorr, less than or about 3 mTorr, less than or about 1 mTorr, or less.

The layer of interface material 310 and/or the layer of coating material 315 may be formed to a thickness of less than or about 3000 nm, such as less than or about 2750 nm, less than or about 2500 nm, less than or about 2250 nm, less than or about 2000 nm, less than or about 1750 nm, less than or about 1500 nm, less than or about 1250 nm, less than or about 1000 nm, less than or about 750 nm, less than or about 500 nm, less than or about 250 nm, less than or about 100 nm, or less. In embodiments, depending on the application, the layer of interface material 310 and/or the layer of coating material 315 may be formed to a much smaller thickness, such as less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, less than or about 2 nm, less than or about 1 nm, or less.

The method 200 and its constituent operations may provide one or more improvements to plasma enhanced deposition processes for depositing materials layers onto a component for semiconductor processing such as by, for example, ALD. For example, the method 200 may provide a coated component for semiconductor processing characterized by a core shell structure, where the core may be or include a ceramic material of the component, such as aluminum nitride or any other ceramic material, with one or more shells, such as a transition metal fluoride or a rare earth fluoride. The shells may be precisely deposited, due to the layer-wise deposition of atomic layer deposition methods, such that the relative composition of the coated component for semiconductor processing may be specified by repeating the operation 215 for a predetermined number of times. Furthermore, the inclusion of an interface between the core and shell may provide one or more desirable properties. For example, the interface may provide CTE modulation between the core and the shell, increase adhesion between the core and the shell, serve as a diffusion barrier, control nucleation, control or remove contamination, or control porosity. Even further, plasma removal of a native passivation layer 305 may improve control of surface chemistry and therefore improves the thermal, mechanical, and/or chemical properties of coated components for semiconductor processing.

In embodiments, the component for semiconductor processing may be characterized by a first CTE. The layer of coating material 315 may be characterized by a second CTE. In order to modulate differences between the first and second CTE, the layer of interface coating 310 may be characterized by a third CTE that is greater than the first CTE and less than the second CTE.

In addition to modulating a larger CTE difference between the component and the layer of coating material, the layer of interface material 310 may provide additional or alternative benefits. The layer of interface material may increase adhesion compared to conventional technologies where the layer of coating material may be formed directly on the component. Additionally, the layer of interface material may control diffusion, nucleation, contamination, and/or porosity. For example, during processing, material from the component, such as metallic material, may begin to diffuse from the component. However, the layer of interface material may reduce or prevent this diffusion, which may also control contamination. The layer of interface material may also reduce or prevent any nucleation that may occur between the component and the layer of coating material. Finally, as previously discussed, the layer of interface material may be characterized by a variety of crystalline structures, including spinel and garnet, which may control porosity.

As will be described further with regard to FIG. 4, the component for semiconductor processing may be, but is not limited to, a lid, a nozzle, a face plate, a gas distribution plate, a heater, a screw, a substrate support, a support platen, a liner, an edge ring, a process kit ring, or a lift pin. These components are commonly exposed to corrosive plasma conditions and may require corrosion-resistant and/or erosion-resistant coatings. By using coated components for semiconductor processing previously discussed, the corrosion-resistant and/or erosion-resistant material may be efficiently formed on the component and may provide desired corrosion and/or erosion resistance.

FIG. 4 show schematic views of an exemplary plasms processing system including one or more components formed by the method according to some embodiments of the present technology. FIG. 4 further illustrates details relating to a semiconductor processing system 400, and one or more components that may be incorporated into system 400 that may be or include a coated component for semiconductor processing. The coated component for semiconductor processing, in turn, may be formed by coating a component for semiconductor processing, such as the coated component for semiconductor processing prepared by the method 200. System 400 is understood to include any feature or aspect of a semiconductor processing chamber, and may be used to perform semiconductor processing operations including deposition, removal, and cleaning operations. System 400 may show a partial view of the chamber components being discussed and that may be incorporated in a typical semiconductor processing system, and may illustrate a view across a center of the pedestal and gas distributor, which may otherwise be of any size. Any aspect of system 400 may also be incorporated with other processing chambers or systems as will be readily understood by the skilled artisan.

System 400 may include a semiconductor processing chamber 450 including a showerhead 405, through which precursors 407 may be delivered for processing, and which may be configured to form a plasma 410 in a processing region between the showerhead 405 and a pedestal or substrate support 415. The showerhead 405 is shown at least partially internal to the chamber 450, and may be understood to be electrically isolated from the chamber 450. In this way, the showerhead 405 may act as a live electrode or as a reference ground electrode of a direct plasma system to expose a substrate held on the substrate support 415 to plasma generated species. The substrate support 415 may extend through the base of the chamber 450. The substrate support 415 may include a support platen 420, which may hold a semiconductor substrate 430 during deposition or removal processes used to form patterned structures on the semiconductor substrate 430.

The support platen 420 may be or include a coated component for semiconductor processing prepared in accordance with embodiments of method 200. The support platen 420 may incorporate embedded electrodes to provide the electrostatic field employed to hold the semiconductor substrate, and may also include a thermal control system that may facilitate processing operations including, but not limited to, deposition, etching, annealing, or desorption. In some embodiments, the support platen 420 may incorporate a plate, a perforated plate, a mesh, a wire screen, or any other distributed arrangement of conductive elements. The embedded electrodes may be or include a tuning electrode to provide further control over the plasma 410, for example, by adjusting an electric field near the surface of the support platen. Similarly, a bias electrode and/or an electrostatic chucking electrode, may be coupled with the support platen 420. The bias electrode may be coupled with a source of electric power, such as a DC power, pulsed DC power, RF bias power, a pulsed RF source or bias power, or a combination of these or other power sources. In this way, the substrate support 415 and the support platen 420 may be used during plasma processing operations not only to hold the semiconductor substrate 430, but also to tune the conditions of the plasma 410. Tuning the conditions of the plasma may include implementing automatic impedance matching to maintain plasma conditions during plasma processing operations, for example, while the composition of the plasma 410 is varied or as the surface of the semiconductor substrate 430 changes, for example, due to deposition of dielectric films onto electrode surfaces. In this way, precise control of the plasma 410 may depend on the material properties of the substrate support 415 and the support platen 420.

In some cases, the support platen 420 or other chamber components may be formed by coating a component for semiconductor processing with a layer of interface material 434 and a layer of coating material 435. For example, a component for semiconductor processing may be treated to form a layer of interface material 434 and then treated to deposit a layer of coating material 435, such as a corrosion-resistant and/or erosion-resistant material, on the layer of interface material 434. Prior and/or subsequent operations, such as annealing, machining, incorporating electrical components, may be applied to finish the component, providing a working component that can be incorporated in a plasma system. An advantage of using a coated component for semiconductor processing, for example, may include that a finished component with one or more layers of coating material 435 may serve as a refractory conductor, with favorable thermal deformation characteristics and chemical resistance to plasma etching, as well as electrical conductivity. Additionally, the layer of interface material 434 may serve to increase the benefits of the layer of coating material 435.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A processing method comprising:
providing a component for semiconductor processing to a processing region of a processing chamber;
providing one or more interface deposition precursors to the processing region;
depositing a layer of interface material on the component for semiconductor processing in the processing region, wherein the layer of interface material comprises an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, or a metal-oxygen-fluorine-and-nitrogen-containing material;
providing one or more coating deposition precursors to the processing region; and
depositing a layer of coating material on the layer of interface material in the processing region.

2. The processing method of claim 1, wherein the component for semiconductor processing comprises a metal-containing material or a metallic-containing material.

3. The processing method of claim 1, wherein the component for semiconductor processing comprises a ceramic-containing material, and wherein the ceramic-containing material comprises one or more metals and one or more of oxygen, fluorine, and nitrogen.

4. The processing method of claim 3, wherein the ceramic-containing material comprises aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}).

5. The processing method of claim 1, wherein the layer of interface material is characterized by a coefficient of thermal expansion (CTE) greater than the component for semiconductor 2 processing and less than the layer of coating material.

6. The processing method of claim 1, wherein the metal-containing precursor comprises aluminum, calcium, erbium, lanthanum, magnesium, scandium, titanium, yttrium, or zirconium.

7. The processing method of claim 1, wherein the one or more coating deposition precursors comprise a fluorine-containing precursor, wherein the fluorine-containing precursor comprises hydrogen fluoride (HF), ammonium fluoride (NH₄F), ammonium bifluoride ([NH₄]F·HF), a HF-pyridine complex, nitrogen trifluoride (NF₃), hexafluoroisopropanol (HFIP), tetrafluoropropanol (TFP), hexafluoro-acetylacetonate (HHFAC), titanium tetrafluoride (TiF₄), tantalum pentafluoride (TaF₅), or tungsten hexafluoride (WF₆), or a fluorine-containing plasma.

8. The processing method of claim 1, wherein the layer of coating material comprises aluminum fluoride (AlF₃), aluminum oxyfluoride (AlOₓF_{y}), calcium fluoride (CaF₂), calcium oxyfluoride (CaOₓF_{y}), magnesium fluoride (MgF₂), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}), or a combination thereof.

9. The processing method of claim 1, wherein the one or more coating deposition precursors further comprise an oxygen-containing precursor.

10. The processing method of claim 8, wherein the oxygen-containing precursor comprises steam (H₂O), molecular oxygen (O₂), ozone (O₃), nitrous oxide (N₂O), hydrogen peroxide (H₂O₂), an oxygen-containing plasma, an alcohol-based compound, or an alcohol-based plasma.

11. The processing method of claim 1, wherein the one or more coating deposition precursors further comprise a nitrogen-containing precursor.

12. The processing method of claim 1, further comprising:
generating plasma effluents of the one or more coating deposition precursors.

13. The processing method of claim 1, wherein a temperature within the processing region is maintained at less than or about 2,000° C.

14. The processing method of claim 13, wherein the component for semiconductor processing comprises a lid, a nozzle, a face plate, a gas distribution plate, a heater, a screw, a substrate support, a support platen, a liner, an edge ring, a process kit ring, or a lift pin.

15. A processing method comprising:
providing a component for semiconductor processing to a processing region of a processing chamber;
depositing a layer of interface material on the component for semiconductor processing in the processing region, wherein the layer of interface material comprises an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, a metal-oxygen-fluorine-and-nitrogen-containing material, a material comprising one or more metals and one or more of oxygen, fluorine, and nitrogen, or combinations thereof;
depositing a layer of coating material on the layer of interface material in the processing region, and wherein depositing the layer of coating material comprises:
exposing the component for semiconductor processing to a first coating precursor;
purging the processing region; and
exposing the component for semiconductor processing to a second coating precursor, wherein the layer of coating material comprises reaction products of the first coating precursor and the second coating precursor, and wherein a temperature within the processing chamber is maintained at greater than or about 400° C.

16. The processing method of claim 15, wherein the component for semiconductor processing comprises aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}).

17. The processing method of claim 15, wherein the layer of coating material comprises a metal-fluorine-and-oxygen-containing material.

18. The processing method of claim 15, further comprising:
generating plasma effluents of the first coating precursor, the second coating precursor, or both.

19. A component for semiconductor processing comprising:
a ceramic, metallic, or non-metallic component for semiconductor processing;
a layer of interface material on the component for semiconductor processing, wherein the layer of interface material comprises an oxygen-containing material, a nitrogen-containing material, a fluorine-containing material, a metal-and-oxygen-containing material, a metal-and-fluorine-containing material, a metal-and-nitrogen-containing material, a metal-oxygen-and-fluorine-containing material, a metal-oxygen-and-nitrogen-containing material, a metal-oxygen-fluorine-and-nitrogen-containing material, a material comprising one or more metals and one or more of oxygen, fluorine, and nitrogen, or combinations thereof; and
a layer of coating material on the layer of interface material.

20. The component for semiconductor processing of claim 19, wherein the component for semiconductor processing comprises a lid, a nozzle, a face plate, a gas distribution plate, a heater, a screw, a substrate support, a support platen, a liner, an edge ring, a process kit ring, or a lift pin.
